(19) United States
(12) Patent Application Publication
(10) Pub. No.: US 2022/0120870 A1
(43) Pub. Date: Apr. 21, 2022

(54) RECEIVING DEVICE AND LASER RADAR INCLUDING THE SAME

(71) Applicant: Hesai Technology Co., Ltd., Shanghai (CN)

(72) Inventors: Kaimin YAN, Shanghai (CN); Shaoqing XIANG, Shanghai (CN)

(73) Assignee: Hesai Technology Co., Ltd., Shanghai (CN)

(21) Appl. No.: 17/565,190

(22) Filed: Dec. 29, 2021

Related U.S. Application Data
(63) Continuation of application No. PCT/CN2020/122664, filed on Oct. 22, 2020.

(30) Foreign Application Priority Data
Nov. 7, 2019 (CN) 201911079332.2

(51) Int. Cl. G01S 7/481; H05K 1/18; H01L 31/107

(52) U.S. Cl. CPC G01S 7/4816; H05K 2201/10151; H01L 31/107; H05K 1/181

(57) ABSTRACT

A receiver for a laser radar, including: a printed circuit board (PCB) substrate, where the PCB substrate includes a first side and a second side; a photoelectric sensor array, including a plurality of photoelectric sensors, where the photoelectric sensor array is disposed on the first side of the PCB substrate; and a readout chip, where the readout chip is disposed on the second side of the PCB substrate, coupled to the photoelectric sensor array, and configured to receive and read an output of a photoelectric sensor in the photoelectric sensor array.

### CROSS-REFERENCE TO RELATED APPLICATIONS

This patent application is a continuation of copending International Application No. PCT/CN2020/122664, filed Oct. 22, 2020, which claims the benefit of Chinese Patent Application No. 201911079332.2, filed Nov. 7, 2019, each of which is incorporated by reference herein in its entirety.

### TECHNICAL FIELD

The present disclosure relates to the field of photoelectric technologies, and in particular, to a receiving device and a laser radar including the same.

### BACKGROUND

A laser radar system is currently widely used in the field of unmanned driving and includes a laser emitting system and a detecting and receiving system. Emitted laser is reflected after encountering a target and is received by the detecting system. A distance of a corresponding target point can be measured by measuring the round-trip time of the laser (such as a time-of-flight method). After an entire target region is scanned and detected, a three-dimensional image can finally be generated. The laser radar system has an important application in an unmanned driving system. In this application, a laser radar is required to have a high imaging frame rate, high resolution, long-distance ranging capability, a small volume, high reliability, and low cost. But it is difficult for a conventional laser radar system to meet such performance.

In existing laser radars, discrete components are usually used to construct the detecting and receiving system. For example, if a 64-line laser radar has 64 avalanche photodiodes (APDs), 64 trans-impedance amplifier (TIA) circuits are needed. When discrete components are used, a larger printed circuit board (PCB) board area is needed for wiring. But considering volume requirements of the radar, it is unreasonable to use a large PCB board. In existing solutions, a plurality of boards are connected through connectors to increase a wiring area, which causes a range of technical defects.

Taking the 64-line laser radar as an example, because the pin spacing among the connectors is small, wires between the 64 APDs and a trans-impedance amplifier need to be assembled together on the connectors first, and then distributed to a receiving plate 1 and a receiving plate 2 after passing through the connectors. On one hand, the electrical separation among the pins is low. On the other hand, the separations among wires corresponding to the pins cannot be increased, and the length of parallel wiring is very long, resulting in relatively low wiring separation, which may cause crosstalk problems between different radar channels.

In addition, different wiring of readout circuits of the 64 APDs leads to different parasitic parameters on the PCB board for different channels, which affects response characteristics of each channel, and causes 64 channels to have high inconsistency in detecting long ranges.

In addition, the gain of an avalanche photodiode APD is very sensitive to temperature, and the 64 APDs on the receiving plate are located at scattered positions on the plate. When the radar is working, temperatures of these positions are not identical, and have a certain gradient. A proper heat dissipation or heat distribution structure can effectively reduce such a gradient. However, a receiving device including 4 PCB boards occupies a large space, and it is difficult to install a heat dissipation or heat distribution structure, which inevitably leads to relatively high gain inconsistency.

The content of this background is merely technologies known to the inventor, and does not represent existing technologies in the field.

### SUMMARY

The present disclosure provides a receiving device for a laser radar, including:

a printed circuit board (PCB) substrate, where the PCB substrate includes a first side and a second side;

a photoelectric sensor array, including a plurality of photoelectric sensors, where the photoelectric sensor array is disposed on the first side of the PCB substrate; and

a readout chip, where the readout chip is disposed on the second side of the PCB substrate, and is configured to receive and read an output of a photoelectric sensor in the photoelectric sensor array.

According to an aspect of the present disclosure, the receiving device further includes a second-stage amplifier, where the second-stage amplifier is disposed on the second side of the PCB substrate, is coupled to the readout chip, and is configured to amplify an output of the readout chip, and

a connection wire between the readout chip and the photoelectric sensor array passes through the PCB substrate.

According to an aspect of the present disclosure, the readout chip includes N packaged trans-impedance amplification circuits and an N-to-1 switch, where an input terminal of each trans-impedance amplification circuit is coupled to one of the photoelectric sensors, and an output terminal is coupled to the N-to-1 switch, and the N-to-1 switch is configured to selectively connect one of the trans-impedance amplification circuits and output an output thereof.

According to an aspect of the present disclosure, the N-to-1 switch is configured to couple an output of one of the trans-impedance amplification circuits to an input terminal of the second-stage amplifier.

According to an aspect of the present disclosure, the receiving device includes a plurality of readout chips, and the photoelectric sensor is an APD.

According to an aspect of the present disclosure, the photoelectric sensor array includes a total of 64 photoelectric sensors, the receiving device includes 4 readout chips, and each readout chip includes 16 trans-impedance amplification circuits and a 16-to-1 switch; or the photoelectric sensor array includes a total of 128 photoelectric sensors, the receiving device includes 8 readout chips, and each readout chip includes 16 trans-impedance amplification circuits and a 16-to-1 switch.

According to an aspect of the present disclosure, the receiving device further includes a bracket, where the PCB substrate is supported on the bracket.

According to an aspect of the present disclosure, the receiving device further includes a heat sink, where the heat sink includes a heat conduction portion and a heat dissipation portion, the heat conduction portion is configured to receive heat from the photoelectric sensor array and/or the readout chip, and the heat dissipation portion is configured to dissipate the heat.

According to an aspect of the present disclosure, the heat dissipation portion includes a plurality of heat-dissipating fins.

According to an aspect of the present disclosure, the photoelectric sensor array includes a ceramic tubular housing, a filter and an aperture, where the photoelectric sensor is attached to the ceramic tubular housing, the filter is disposed on the photoelectric sensor to filter stray light, and the aperture is disposed on the filter to limit a light beam incident on the photoelectric sensor.

According to an aspect of the present disclosure, the readout chip includes a DAC voltage regulator, where an output terminal of the DAC voltage regulator is coupled to an output terminal of the photoelectric sensor, for adjusting a bias voltage at both ends of the photoelectric sensor.

The present disclosure further relates to a laser radar, including the receiving device as described above.

According to an aspect of the present disclosure, the laser radar includes one receiving device.

Through the technical solution of the embodiments of the present disclosure, the gain and bandwidth consistency among channels of the readout chip can be far better than that of discrete devices, which contributes to high distance ranging consistency of a receiving terminal; positions of reduced circuit boards spare a larger space for heat dissipation and heat distribution structures to reduce a temperature gradient of a plurality of APDs; and an APD array can have better use value. The APD array on the front may be in a one-to-one correspondence with positions of input pins of a self-developed chip on the back, and wires are not crossed and are extremely short. In addition, by using the APD array, an assembly and adjustment process can be greatly simplified.

### BRIEF DESCRIPTION OF THE DRAWINGS

The accompanying drawings constituting a part of the present disclosure are used to provide a further understanding of the present disclosure. The exemplary embodiments of the present disclosure and descriptions thereof are used to explain the present disclosure, and do not constitute an improper limitation to the present disclosure. In the accompanying drawings,

FIG. 1 illustrates a receiving device according to an embodiment of the present disclosure;

FIG. 2 illustrates a schematic diagram of a readout chip according to an exemplary embodiment of the present disclosure;

FIG. 3A illustrates a receiving device according to an exemplary embodiment of the present disclosure;

FIG. 3B illustrates an assembly view of a PCB substrate, a bracket, and a heat dissipation portion;

FIG. 4 illustrates a schematic diagram of a photoelectric sensor array according to an exemplary embodiment of the present disclosure;

FIG. 5A illustrates a schematic diagram of a photoelectric sensor array and a readout chip according to an exemplary embodiment of the present disclosure; and

FIG. 5B illustrates a schematic diagram of a photoelectric sensor array and a readout chip according to another exemplary embodiment of the present disclosure.

### DETAILED DESCRIPTION

Only certain exemplary embodiments are briefly described below. As understood by those skilled in the art, the described embodiments may be modified in various different ways without departing from the spirit or the scope of the present disclosure. Therefore, the drawings and the descriptions are to be considered as illustrative in nature but not restrictive.

In the present disclosure, it should be understood that orientation or position relationships indicated by terms such as “center”, “longitudinal”, “transverse”, “length”, “width”, “thickness”, “upper”, “lower”, “front”, “rear”, “left”, “right”, “vertical”, “horizontal”, “top”, “bottom”, “inner”, “outer”, “clockwise”, and “counterclockwise” are orientation or position relationships shown based on the accompanying drawings, and are merely used to facilitate describing the present disclosure and for simplifying the description, rather than indicating or implying that a mentioned device or element must have a particular orientation or must be constructed and operated in a particular orientation. Therefore, such terms should not be construed as a limitation to the present disclosure. In addition, the terms “first” and “second” are used merely for the purpose of description, and should not be construed as indicating or implying relative importance or implying a quantity of indicated technical features. Therefore, a feature restricted by “first” or “second” may explicitly or implicitly include one or more such features. In the present disclosure, unless otherwise explicitly specified, “a plurality of” means two or more than two.

In the present disclosure, it should be noted that, unless otherwise explicitly specified or defined, terms “mount”, “connect”, and “couple” should be understood in a broad sense, for example, the connection may be a fixed connection, a detachable connection, or an integral connection; or the connection may be a mechanical connection, or may be an electrical connection, or may communicate with each other; or the connection may be a direct connection, an indirect connection by using an intermediary, or internal communication between two components or mutual interaction relationship between two components. A person of ordinary skill in the art may understand the specific meanings of the foregoing terms in the present disclosure according to specific situations.

In the present disclosure, unless otherwise explicitly specified and defined, that a first feature is “above” or “below” a second feature may include that the first and second features are in direct contact, or may include that the first and second features are not in direct contact but in contact by using other features therebetween. In addition, that the first feature is “on”, “above”, or “over” the second feature includes that the first feature is right above and on the inclined top of the second feature or merely indicates that a level of the first feature is higher than that of the second feature. That the first feature is “below”, “under”, or “beneath” the second feature includes that the first feature is right below and at the inclined bottom of the second feature or merely indicates that a level of the first feature is lower than that of the second feature.

Implementations or examples are provided in the following disclosure to implement various structures of the present disclosure. To simplify the disclosure of the present disclosure, components and settings in particular examples are described below. Certainly, they are merely examples and are not intended to limit the present disclosure. In addition, in the present disclosure, reference numerals and/or reference letters may be repeated in different examples. The repetition is for the purposes of simplification and clearness, and does not indicate a relationship between various implementations and/or settings that are discussed. Moreover, the present disclosure provides examples of certain particular processes and materials, but a person of ordinary skill in the art may be aware of application of another process and/or use of another material.

Exemplary embodiments of the present disclosure are described below with reference to the accompanying drawings. It should be understood that the exemplary embodiments described herein are merely used to describe and explain the present disclosure but are not intended to limit the present disclosure.

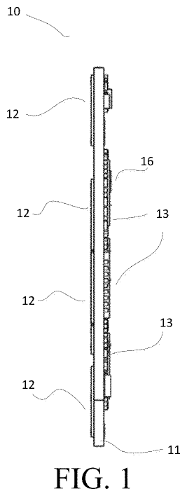

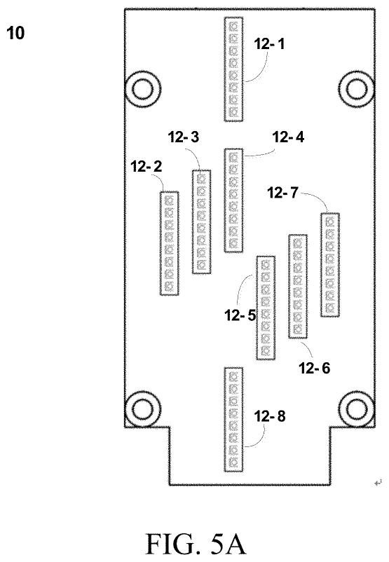

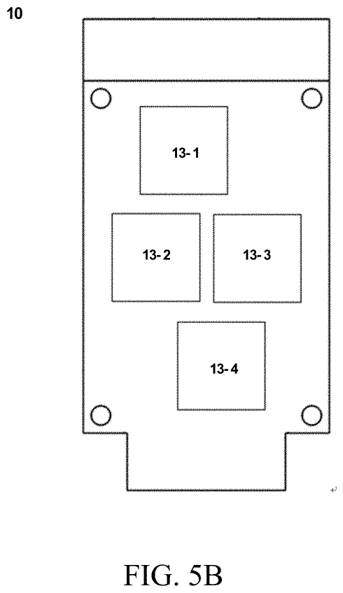

FIG. 1 illustrates a receiving device 10 according to an embodiment of the present disclosure, which may be applicable to a laser radar, for example, to receive echo beams reflected from an obstacle outside the laser radar. Detailed description is given below with reference to FIG. 1. As shown in FIG. 1, the receiving device 10 includes a PCB substrate 11, a photoelectric sensor array 12 and a readout chip 13, where the PCB substrate 11 serves as a mechanical support substrate and a circuit substrate, and other photoelectric components of the receiving device 10 can be disposed on the PCB substrate 11. As shown in FIG. 1, the PCB substrate 11 is in the shape of a thin plate and includes a first side and a second side, which correspond to a left side and a right side as shown in FIG. 1, respectively. The receiving device 10 may include one or more photoelectric sensor arrays 12 disposed on the first side of the PCB substrate 11, where each photoelectric sensor array 12 includes a plurality of photoelectric sensors. The photoelectric sensor is, for example, a photodiode, and an avalanche photodiode (APD) or silicon photomultipliers (SiPM). After receiving an incident beam or photons, the photoelectric sensor generates a corresponding electrical signal according to intensity of the incident beam or the quantity of the photons. After being collected, amplified, and filtered, the electrical signal can be used for subsequent data processing to generate point cloud data for a laser radar. FIG. 1 shows that the PCB substrate 11 is provided with four photoelectric sensor arrays 12. A person skilled in the art can easily understand that the present disclosure is not limited thereto. The quantity of photoelectric sensor arrays 12 can be freely determined as required, or determined according to arrangement positions and manners of the photoelectric sensors 12. For example, FIG. 5A shows that 8 photoelectric sensor arrays 12 are disposed on the PCB substrate 11, and each photoelectric sensor array includes 8 photoelectric sensors. In addition, the quantity of photoelectric sensors included in each photoelectric sensor array 12 can also be selected as required. For example, when applied to a 64-line laser radar, four groups of photoelectric sensor arrays can be selected and disposed, and each photoelectric sensor array includes 16 photoelectric sensors. All fall within the protection scope of the present disclosure.

The readout chip 13 is disposed on the second side of the PCB substrate 11, opposite to the photoelectric sensor array 12 and coupled to the photoelectric sensor array 12, and is configured to receive and read an output of a photoelectric sensor in the photoelectric sensor array 12. As shown in FIG. 1, the photoelectric sensor array 12 and the readout chip 13 are respectively disposed on opposite sides of the PCB substrate 11. Therefore, according to exemplary embodiment of the present disclosure, a connection wire connecting the readout chip 13 and the photoelectric sensor array 12 can pass through an interior of the PCB substrate 11, and an external wire of the PCB 11 can be reduced or avoided. Therefore, the length of parallel wires is reduced and wiring isolation is improved, and crosstalk problems between different channels of a laser radar are reduced.

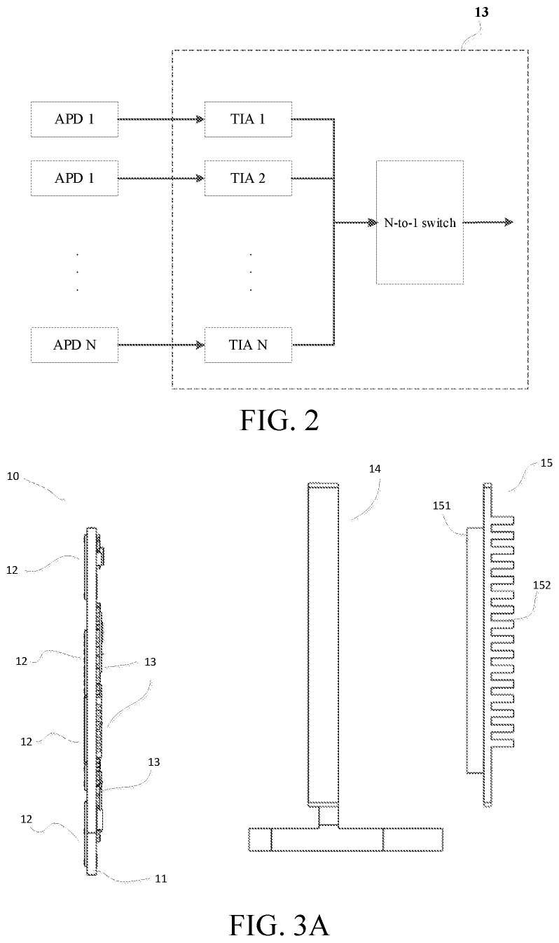

FIG. 2 illustrates a schematic diagram of a readout chip 13 according to an exemplary embodiment of the present disclosure. The readout chip 13 is, for example, a multi-channel readout chip, which is disposed on the second side of the PCB substrate. As shown in FIG. 2, the readout chip 13 includes N packaged trans-impedance amplification circuit (TIA1, TIA2, . . . , TIAN) and an N-to-1 switch. An input terminal of each trans-impedance amplification circuit is coupled to one of the photoelectric sensors, such as an APD, so as to receive an electrical signal of the photoelectric sensor, and perform signal amplification and output. An input terminal of each trans-impedance amplification circuit is coupled to the N-to-1 switch, and the N-to-1 switch is configured to connect one of the trans-impedance amplification circuits and output an output thereof.

According to an exemplary embodiment of the present disclosure, the readout chip 13 may correspond to the photoelectric sensor array, so that the quantity of the readout chips 13 is the same as the quantity of the photoelectric sensor arrays, for example, are both 4, 3, 2, or 1. For example, for a 64-line laser radar, 4 photoelectric sensor arrays 12 may be included, and each photoelectric sensor array 12 includes 16 APDs. Correspondingly, the receiving device 10 includes 4 readout chips 13, and each readout chip 13 includes 16 trans-impedance amplification circuits and a 16-to-1 switch. Therefore, a readout chip is equivalent to 16 discrete TIA trans-impedance circuits and a 16-to-1 analog switch. By using only 4 readout chips, for example, adding a second-stage amplification circuit, the same functions as that of an original receiving system can be achieved, so that a receiving terminal only needs to use a PCB board with the same area as that of an original one to complete wiring. Optionally, the quantity of the readout chips 13 and the quantity of the photoelectric sensor arrays may also be different. FIG. 5A and FIG. 5B illustrate such an embodiment. As shown in FIG. 5A, eight photoelectric sensor arrays 12 are disposed on the first side of the PCB substrate 11; and as shown in FIG. 5B, four readout chips 13 are disposed on the second side of the PCB substrate 11, and each readout chip 13 is coupled to one or more photoelectric sensor arrays 12 and reads an output of the photoelectric sensor array 12. In addition, for example, a connection relationship between the readout chip 13 and the photoelectric sensor array 12 can be determined according to position distribution thereof, so as to minimize the wiring length. For example, in FIG. 5A, there are 8 photoelectric sensor arrays 12, respectively 12-1, 12-2, . . . , and 12-8, where the photoelectric sensors 12-2, 12-3, and 12-4 are located close to each other, the photoelectric sensors 12-5, 12-6, and 12-7 are located close to each other, and the other two photoelectric sensors 12-1 and 12-8 are located independent of each other. Accordingly, positions of the four readout chips 13 disposed on the second side of the PCB substrate 11 respectively correspond to positions of the photoelectric sensors. For example, a position of a readout chip 13-1 roughly corresponds to the photoelectric sensor 12-1, a position of a readout chip 13-2 roughly corresponds to the photoelectric sensors 12-2, 12-3, 12-4, a position of a readout chip 13-3 roughly corresponds to the photoelectric sensors 12-5, 12-6, 12-7, and a position of a readout chip 13-4 roughly corresponds to the photoelectric sensor 12-8. Through such an arrangement, the length of a wire connecting the readout chip 13 and the photoelectric sensor array 12 can be further reduced, and the wiring isolation can be improved, to reduce crosstalk problems between different channels of a laser radar.

Or, for a 128-line laser radar, 8 photoelectric sensor arrays, namely, a total of 128 photoelectric sensors may be included. The receiving device includes 8 readout chips, and each readout chip includes 16 trans-impedance amplification circuits and a 16-to-1 switch.

In addition, according to an exemplary embodiment of the present disclosure, as shown in FIG. 1, the receiving device 10 further includes a second-stage amplifier 16, where the second-stage amplifier 16 is disposed on the second side of the PCB substrate and on the same side as the readout chip 13. The second-stage amplifier 16 is coupled to the readout chip 13 so as to perform secondary amplification on a signal output by the readout chip 13.

According to the embodiments of FIG. 1 and FIG. 2, the N-to-1 switch may be configured to couple an output of one of the trans-impedance amplification circuits to an input terminal of the second-stage amplifier. The N-to-1 switch has, for example, N input channels, connects one of the input channels, and outputs an input of the input channel.

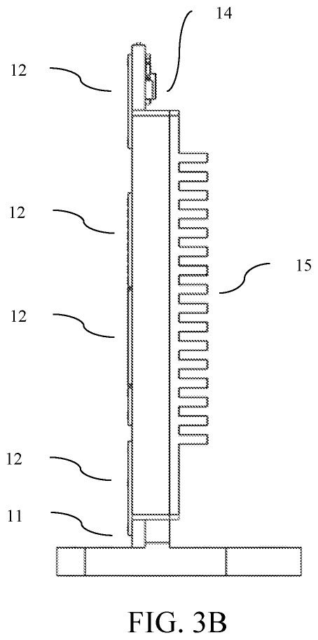

FIG. 3A illustrates a receiving device 10 according to an exemplary embodiment of the present disclosure which further includes a bracket 14 and the PCB substrate 11 being supported on the bracket 14. The bracket 14 is usually made of higher-strength metal, and is configured to mount and secure the receiving device, for example, to fix the receiving device to a base of a laser radar. In addition, the receiving device 10 in FIG. 3A further includes a heat sink 15, where the heat sink 15 includes a heat conduction portion (or a heat-absorbing portion) 151 and a heat dissipation portion 152. The heat conduction portion 151 is made of a material with a high thermal conductivity, and for example, is in contact with or close to the photoelectric sensor array 12 and/or the readout chip 13, so as to absorb heat generated by the photoelectric sensor array and/or the readout chip. The absorbed heat is conducted to the heat dissipation portion 152, and then dissipated through the heat dissipation portion 152. In an exemplary embodiment, a fan or another device that can promote air flow may be disposed near the heat dissipation portion 152 to facilitate heat dissipation. As shown in FIG. 2, the heat dissipation portion 152 includes a plurality of heat-dissipating fins. As alternatives to the latter, the heat dissipation portion 152 includes spirally-shaped heat dissipation walls to increase a heat dissipation area and enhance a heat dissipation effect.

FIG. 3B illustrates an assembly view of the PCB substrate 11, the bracket 14, and the heat dissipation portion 152.

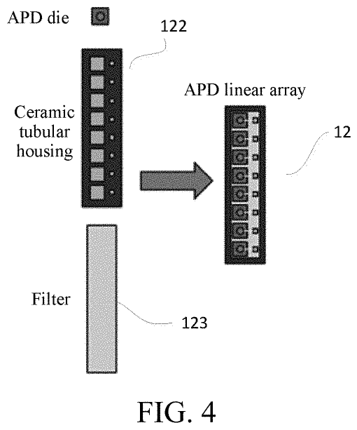

The photoelectric sensor array 12 may include a plurality of discrete photoelectric sensors. In an exemplary embodiment, a plurality of photoelectric sensors in the photoelectric sensor array 12 are appropriately grouped and packaged, as described below with reference to FIG. 4, FIG. 5A, and FIG. 5B.

FIG. 4 illustrates a schematic diagram of a photoelectric sensor array 12 according to an exemplary embodiment of the present disclosure. As shown in FIG. 4, in addition to a plurality of photoelectric sensors, such as APD dies, the photoelectric sensor array 12 further includes a ceramic tubular housing 122 and a filter 123, where the APD dies are attached to the ceramic tubular housing 122, and the filter 123 is disposed on the APD dies to filter stray light. Therefore, a packaged APD linear array can be formed, which can be directly mounted on the receiving device 10 of a laser radar. In addition, optionally, the photoelectric sensor array may further include an aperture structure, which is disposed upstream of an optical path of the photoelectric sensor, for example, disposed on the filter 123, which can also be used to prevent or reduce incidence of stray light on the photoelectric sensor to reduce noise.

FIG. 4 shows that a plurality of APDs is disposed and packaged into an APD linear array. A person skilled in the art can easily understand that the protection scope of the present disclosure is not limited thereto. It can also be a single APD package, or disposed and packaged in other two-dimensional patterns. In addition, a single or a plurality of APD arrays can also be used to further arrange and combine a linear array or a planar array on the PCB substrate. All fall within the protection scope of the present disclosure. FIG. 5A is a schematic diagram of a photoelectric sensor array 12 according to an embodiment of the present disclosure. It is exemplarily shown that the photoelectric sensor array includes 8 APDs, where there are a total of 8 photoelectric sensor arrays, and each array uses, for example, the packaging manner shown in FIG. 4. Certainly, the quantity and arrangement manner shown in FIG. 5A are merely illustrative. For example, the quantity of APDs can be 16, 32, 64, or 128, and the quantity of APDs included in each package is not limited to 8, and can be adjusted accordingly according to actual requirements.

In addition, according to an aspect of the present disclosure, the readout chip includes a DAC voltage regulator, where an output terminal of the DAC voltage regulator is coupled to an output terminal of the photoelectric sensor, for adjusting a bias voltage at both ends of the photoelectric sensor. In an exemplary embodiment, the quantity of the DAC voltage regulators corresponds to the quantity of the photoelectric sensors, so that a bias voltage can be adjusted individually for each photoelectric sensor, to control a gain coefficient of the photoelectric sensor.

An embodiment of the present disclosure further relates to a laser radar, including the receiving device 10 described above.

In addition, according to an embodiment of the present disclosure, in the laser radar, only one receiving device is included. In this way, all the photoelectric sensors and the readout chips can be integrated on the same PCB substrate, so that each channel of a laser radar has high distance ranging consistency. In addition, the photoelectric sensors are located on the same PCB substrate, temperature is relatively uniform, and therefore a temperature gradient therebetween can be reduced, so that gains of the photoelectric sensors may be as consistent as possible.

Embodiments of the present disclosure have advantages of multi-function and modularization, and a series of functions are comprehensively considered and optimized, for example, problems such as packaging reliability, volume, cost, electromagnetic compatibility, light filtering, optical crosstalk between channels, assembly and adjustment, and heat dissipation. In addition, a scheme of the present disclosure can be adapted to a plurality of scanning laser radar system schemes, for example: a mechanical scanning type, a rotating mirror scanning type, and a galvanometer scanning type.

In addition, the scheme of the embodiments of the present disclosure has features of easy production and easy assembly and calibration. Precise position arrangement of the photoelectric sensors such as APDs can be automated by machines; and an APD planar array can be assembled and adjusted as a whole, to reduce the difficulty and costs of assembly and adjustment. Through a filter and an aperture, the embodiments of the present disclosure have features of a high signal-to-noise ratio and low crosstalk, which can suppress crosstalk and stray light. Furthermore, because the photoelectric sensor array and the readout chip are disposed on two sides of the same PCB substrate, connection wires can be disposed through the PCB substrate. As a result, the connection wires are short, and therefore the present disclosure has low parasitic capacitance, resulting in high bandwidth and low circuit noise.

Besides, by using metal structures to manufacture structures such as brackets, apertures and heat sinks, sensitive front-end detectors and circuits can be shielded and protected from interference, having strong electromagnetic compatibility.

Advantages of the embodiments of the present disclosure include but are not limited to:

reduction or elimination of the use of connectors. On one hand, there is no limitation of electrical separation caused by pin spacing. Also, the readout chip fully considers APD layout and optimizes chip pin layout. There are direct current (DC) pins between chip pins of adjacent channels for isolation, which can also increase a distance between adjacent wires. On the other hand, wires from an APD to a trans-impedance amplifier can go directly from the front to the back of the PCB board, without any detour in the middle, which greatly shortens the length of parallel wires, and crosstalk problems between channels can be significantly resolved.

The gain and bandwidth consistency between channels of the readout chip can be far better than that of discrete devices, which causes the receiving terminal to have high consistency in detecting long ranges.

The reduced circuit boards spare a relatively large empty space, and heat dissipation and heat distribution structures can be added to reduce a temperature gradient of a plurality of APDs.

The introduction of the readout chip enables an APD array to have higher utilization value. The APD array on the front is in a one-to-one correspondence with positions of input pins of a self-developed chip on the back, and wires are not crossed and are extremely short. In addition, by using the APD array, an assembly and adjustment process can be greatly simplified.

The foregoing descriptions are merely certain exemplary embodiments of the present disclosure, but are not intended to limit the present disclosure. Any modification, equivalent replacement, or improvement made within the spirit and principle of the present disclosure shall fall within the protection scope of the present disclosure.

It should be finally noted that the foregoing descriptions are merely exemplary embodiments of the present disclosure, but are not intended to limit the present disclosure. Although the present disclosure has been described in detail with reference to the foregoing embodiments, for a person of ordinary skill in the art, modifications can still be made to the technical solutions described in the foregoing embodiments, or equivalent replacements can be made to some technical features in the technical solutions. Any modification, equivalent replacement, or improvement made within the spirit and principle of the present disclosure shall fall within the protection scope of the present disclosure.

What is claimed is:

1. A receiver for a laser radar, the receiver comprising:
a printed circuit board (PCB) substrate, wherein the PCB substrate comprises a first side and a second side;
a photoelectric sensor array, comprising a plurality of photoelectric sensors, wherein the photoelectric sensor array is disposed on the first side of the PCB substrate; and
a readout chip, wherein the readout chip is disposed on the second side of the PCB substrate, and is configured to receive and read an output of a photoelectric sensor in the photoelectric sensor array, and wherein the readout chip and the photoelectric sensor array are connected by a connection wire passing through the PCB substrate.

2. The receiver according to claim 1, further comprising a second-stage amplifier, wherein the second-stage amplifier is: disposed on the second side of the PCB substrate, coupled to the readout chip, and configured to amplify an output of the readout chip.

3. The receiver according to claim 2, wherein the readout chip comprises N packaged trans-impedance amplification circuits and an N-to-1 switch, wherein an input terminal of each trans-impedance amplification circuit is coupled to a photoelectric sensor in the photoelectric sensor array, and an output terminal of each trans-impedance amplification circuit is coupled to the N-to-1 switch, and the N-to-1 switch is configured to selectively connect one of the trans-impedance amplification circuits to the output of the readout chip.

4. The receiver according to claim 3, wherein the N-to-1 switch is configured to couple an output of one of the trans-impedance amplification circuits to an input terminal of the second-stage amplifier.

5. The receiver according to claim 3, wherein the readout chip comprises a plurality of readout chips, and the photoelectric sensor is an avalanche photodiode (APD).

6. The receiver according to claim 5, wherein the photoelectric sensor array comprises 64 photoelectric sensors, the plurality of readout chips comprises four readout chips, and each readout chip comprises 16 trans-impedance amplification circuits and a 16-to-1 switch; or wherein the photoelectric sensor array comprises 128 photoelectric sensors, the plurality of readout chips comprises eight readout chips, and each readout chip comprises 16 trans-impedance amplification circuits and a 16-to-1 switch.

7. The receiver according to claim 1, further comprising a bracket, wherein the PCB substrate is supported on the bracket.

8. The receiver according to claim 7, further comprising a heat sink, wherein the heat sink comprises a heat conduction portion and a heat dissipation portion, the heat conduction portion is configured to receive heat from the photoelectric sensor array and/or the readout chip, and the heat dissipation portion is configured to dissipate the heat.

9. The receiver according to claim 8, wherein the heat dissipation portion comprises a plurality of heat-dissipating fins.

10. The receiver according to claim 1, wherein the photoelectric sensor array comprises a ceramic tubular housing, a filter and an aperture, wherein the photoelectric sensor in the photoelectric sensor array is attached to the ceramic tubular housing, the filter is disposed on the photoelectric sensor to filter stray light, and the aperture is disposed on the filter to limit a light beam incident on the photoelectric sensor.

11. The receiver according to claim 1, wherein the readout chip comprises a digital to analog converter (DAC) voltage regulator, and an output terminal of the DAC voltage regulator is coupled to an output terminal of the photoelectric sensor for adjusting a bias voltage at both ends of the photoelectric sensor.

12. A laser radar, comprising a receiver, wherein the receiver comprises:
a printed circuit board (PCB) substrate, wherein the PCB substrate comprises a first side and a second side;
a photoelectric sensor array, comprising a plurality of photoelectric sensors, wherein the photoelectric sensor array is disposed on the first side of the PCB substrate; and
a readout chip, wherein the readout chip is disposed on the second side of the PCB substrate, and is configured to receive and read an output of a photoelectric sensor in the photoelectric sensor array, and wherein the readout chip and the photoelectric sensor array are connected by a connection wire passing through the PCB substrate.

13. The laser radar according to claim 12, wherein the receiver further comprises a second-stage amplifier, wherein the second-stage amplifier is: disposed on the second side of the PCB substrate, coupled to the readout chip, and configured to amplify an output of the readout chip.

14. The laser radar according to claim 13, wherein the readout chip comprises N packaged trans-impedance amplification circuits and an N-to-1 switch, wherein an input terminal of each trans-impedance amplification circuit is coupled to a photoelectric sensor in the photoelectric sensor array, and an output terminal of each trans-impedance amplification circuit is coupled to the N-to-1 switch, and the N-to-1 switch is configured to selectively connect one of the trans-impedance amplification circuits to the output of the readout chip.

15. The laser radar according to claim 14, wherein the N-to-1 switch is configured to couple an output of one of the trans-impedance amplification circuits to an input terminal of the second-stage amplifier.

16. The laser radar according to claim 14, wherein the readout chip comprises a plurality of readout chips, and the photoelectric sensor is an avalanche photodiode (APD).

17. The laser radar to claim 16, wherein the photoelectric sensor array comprises 64 photoelectric sensors, the plurality of readout chips comprises four readout chips, and each readout chip comprises 16 trans-impedance amplification circuits and a 16-to-1 switch; or wherein the photoelectric sensor array comprises 128 photoelectric sensors, the plurality of readout chips comprises eight readout chips, and each readout chip comprises 16 trans-impedance amplification circuits and a 16-to-1 switch.

18. The laser radar according to claim 12, wherein the receiver further comprises a bracket, wherein the PCB substrate is supported on the bracket.

19. The laser radar according to claim 18, wherein the receiver further comprises a heat sink, wherein the heat sink comprises a heat conduction portion and a heat dissipation portion, the heat conduction portion is configured to receive heat from the photoelectric sensor array and/or the readout chip, and the heat dissipation portion is configured to dissipate the heat.

20. The laser radar according to claim 19, wherein the heat dissipation portion comprises a plurality of heat-dissipating fins.
